(19) United States
(12) Patent Application Publication
(10) Pub. No.: US 2019/0319064 A1
(43) Pub. Date: Oct. 17, 2019

(54) MICRO LED DISPLAY AND METHOD OF MANUFACTURING THE SAME

(71) Applicant: ASTI GLOBAL INC., TAIWAN, Changhua County (TW)

(72) Inventor: CHIEN-SHOU LIAO, New Taipei City (TW)

(21) Appl. No.: 16/154,132

(22) Filed: Oct. 8, 2018

(30) Foreign Application Priority Data
Apr. 11, 2018 (TW) 107112397

(51) Int. Cl. H01L 27/15; H01L 25/075; H01L 33/62

(52) U.S. Cl. CPC H01L 27/156; H01L 2933/0066; H01L 33/62; H01L 25/0753

(57) ABSTRACT

A micro LED display and method of manufacturing the same are provided. The micro LED display includes a wafer level substrate, an adhesive layer, a plurality of light emitting assemblies and a conductive structure. The wafer level substrate includes a plurality of control circuits, wherein each of the control circuits has a conductive contact. The adhesive layer is disposed on the wafer level substrate. Each of the light emitting assemblies includes a plurality of light emitting diode structures disposed on the adhesive layer. The conductive structure is electrically connected between the light emitting diode structure and the control circuit, which are corresponding to each other.

### CROSS-REFERENCE TO RELATED PATENT APPLICATION

This application claims the benefit of priority to Taiwan Patent Application No. 107112397, filed on Apr. 11, 2018. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a display and a method of manufacturing the same, and more particularly to a micro LED display and a method of manufacturing the same.

### BACKGROUND OF THE DISCLOSURE

A light emitting diode (LED) is now widely used because of its excellent light quality and high luminous efficiency. Generally, in order to enhance color performance of the display device which uses an LED as a light emitting assembly, in the prior art a combination of red, green, and blue LED chips is used to form a full-color LED display device. The full-color LED display device can emit red, green and blue colors respectively through the red, green and blue LED chips, and then form a full-color light by mixing lights to display related information. However, the conventional LED display and the manufacturing method thereof still need to be improved.

### SUMMARY OF THE DISCLOSURE

In response to the above-referenced technical inadequacies, the present disclosure provides a micro LED display and method of manufacturing the same.

In one aspect, the present disclosure provides a micro LED display including a wafer level substrate, an adhesive layer, a plurality of light emitting assemblies, an insulating layer, and a conductive structure. The wafer level substrate includes a wafer body, a plurality of control circuits built in the wafer body, and a plurality of ground circuits built in the wafer body. Each of the control circuits has a conductive contact exposed outside of the wafer body and each of the ground circuits has a ground contact exposed outside of the wafer body. The adhesive layer is disposed on the wafer body. Each of the light emitting assemblies includes a plurality of light emitting diode structures, which are disposed on the adhesive layer without contacting the wafer level substrate, and each of the light emitting diode structures has a first electrode end and a second electrode end. The insulating layer is formed on the wafer level substrate and the light emitting assemblies, and the conductive contact of each of the control circuits, the ground contact of each of the control circuits, and the first electrode end and the second electrode end of each of the light emitting diode structures are exposed from the insulating layer. The conductive structure includes a plurality of first conductive layers and a plurality of second conducive layers, each of the first conductive layers is electrically connected between the corresponding first electrode end and the corresponding conductive contact, and each of the second conductive layers is electrically connected between the corresponding second electrode end and the corresponding ground contact. In addition, the light emitting assemblies are disposed adjacent to each other, such that the light emitting diode structures of the light emitting assemblies are arranged into a pixel array.

In one aspect, the present disclosure provides a micro LED display including a wafer level substrate, which includes a wafer level substrate, an adhesive layer, a plurality of light emitting assemblies, and a conductive structure. The wafer level substrate includes a plurality of control circuits, and each of the control circuits has a conductive contact. The adhesive layer is disposed on the wafer level substrate. Each of the light emitting assemblies has a plurality of light emitting diode structures, which are disposed on the adhesive layer. The conductive structure is electrically connected between the corresponding light emitting diode structure and the corresponding control circuit. In addition, the light emitting assemblies are disposed adjacent to each other, such that the light emitting diode structures of the light emitting assemblies are arranged into a pixel array.

In one another aspect, the present disclosure further provides a method of manufacturing a micro LED display including the following steps: providing a wafer level substrate which includes a plurality of control circuits, wherein each of the control circuits has a conductive contact; connecting a plurality of composite structures and the wafer level substrate by an adhesive layer; removing a basal layer of each of the composite structures and remaining a retention layer of each of the composite structures; processing the retention layers of the composite structures into a plurality of light emitting diode structures which are disposed on the adhesive layer; and forming a conductive structure to electrically connected between the corresponding light emitting diode structure and the corresponding control circuit.

Therefore, each of the light emitting assemblies which includes the light emitting diode structures and the wafer level substrate which includes the control contacts are connected with each other by the adhesive layer with the features of “the adhesive layer is disposed on the wafer level substrate and each of the light emitting assemblies includes the light emitting diode structures disposed on the adhesive layer” or “connecting a plurality of composite structures and the wafer level substrate by an adhesive layer, removing a basal layer of each of the composite structures and remaining a retention layer of each of the composite structures, and processing the retention layers of the composite structures into a plurality of light emitting diode structures which are disposed on the adhesive layer”.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The present disclosure will become more fully understood from the detailed description and the accompanying drawings, in which:

FIG. 1 is a flowchart of a method of manufacturing a micro LED display according to a first embodiment of the present disclosure.

FIG. 2 is a schematic view showing step S100 of the method of manufacturing a micro LED display according to the first embodiment of the present disclosure.

FIG. 3 is a schematic view showing step S1021 of the method of manufacturing a micro LED display according to the first embodiment of the present disclosure.

FIG. 4 is a schematic view showing step S1023 of the method of manufacturing a micro LED display according to the first embodiment of the present disclosure.

FIG. 5 is a schematic view showing step S102(A) of the method of manufacturing a micro LED display according to the first embodiment of the present disclosure.

FIG. 6 is a schematic view showing step S104(A) of the method of manufacturing a micro LED display according to the first embodiment of the present disclosure.

FIG. 7 is a schematic view showing step S106(A) of the method of manufacturing a micro LED display according to the first embodiment of the present disclosure.

FIG. 8 is a schematic view showing step S108(A) of the method of manufacturing a micro LED display according to the first embodiment of the present disclosure.

FIG. 9 is a schematic view showing step S110(A) of the method of manufacturing a micro LED display according to the first embodiment of the present disclosure.

FIG. 10 is a flowchart of a method of manufacturing a micro LED display according to a second embodiment of the present disclosure.

FIG. 11 is a schematic view showing step S102(B) of the method of manufacturing a micro LED display according to the second embodiment of the present disclosure.

FIG. 12 is a schematic view showing step S104(B) of the method of manufacturing a micro LED display according to the second embodiment of the present disclosure.

FIG. 13 is a schematic view showing step S106(B) of the method of manufacturing a micro LED display according to the second embodiment of the present disclosure.

FIG. 14 is a schematic view showing step S108(B) of the method of manufacturing a micro LED display according to the second embodiment of the present disclosure.

FIG. 15 is a schematic view showing step S110(B) of the method of manufacturing a micro LED display according to the second embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

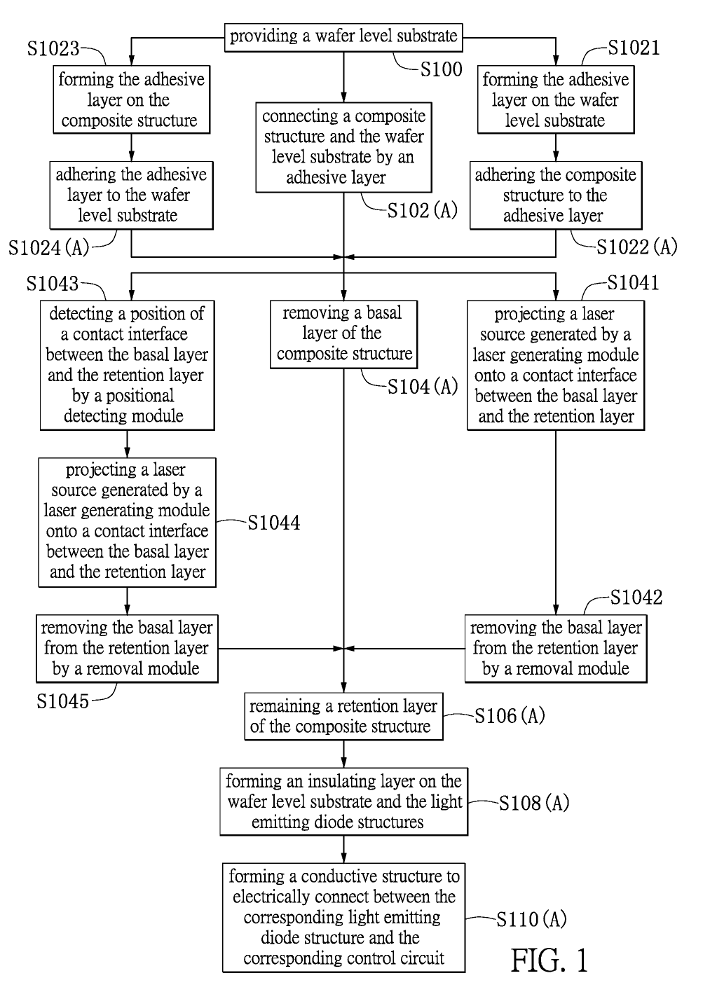

Referring to FIG. 1, a first embodiment of the present disclosure provides a method of manufacturing a micro LED display includes the steps as follows.

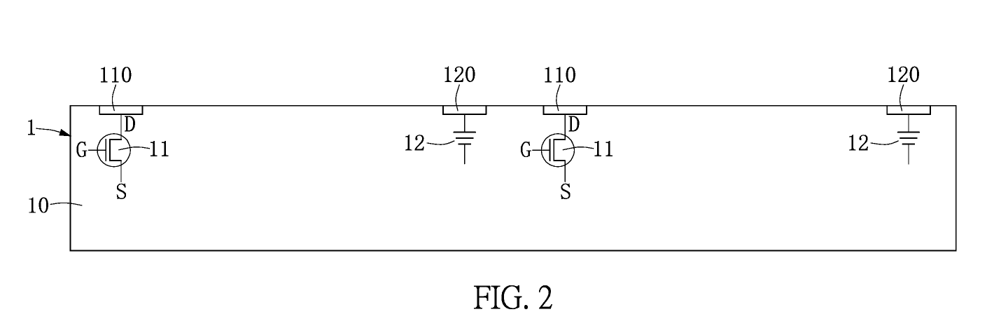

First, as shown in FIG. 1 and FIG. 2, a wafer level substrate 1 is provided and includes a plurality of control circuits 11, and each of the control circuits 11 has a conductive contact 110 (step S100). Further, the wafer level substrate 1 includes a wafer body 10, a plurality of control circuits 11 built in the wafer body 10, and a plurality of ground circuits 12 built in the wafer body 10. In addition, each of the control circuits 11 has a conductive contact 110 exposed outside of the wafer body 10 and each of the ground circuits 12 has a ground contact 120 exposed outside the wafer body 10. For instance, the wafer level substrate can be a silicon wafer, epitaxial silicon wafer, argon anneal silicon wafer, hai silicon wafer, or silicon on insulator silicon wafer, and the control circuit can be a complementary metal-oxide-semiconductor (CMOS) control circuit, which has a source S, a drain D, and a gate G, but the present disclosure is not limited thereto.

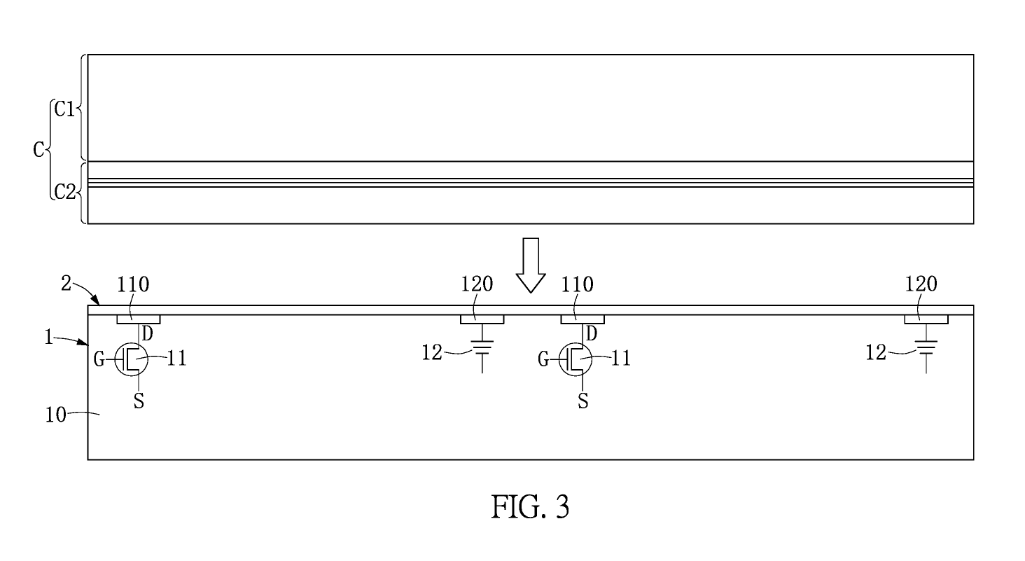

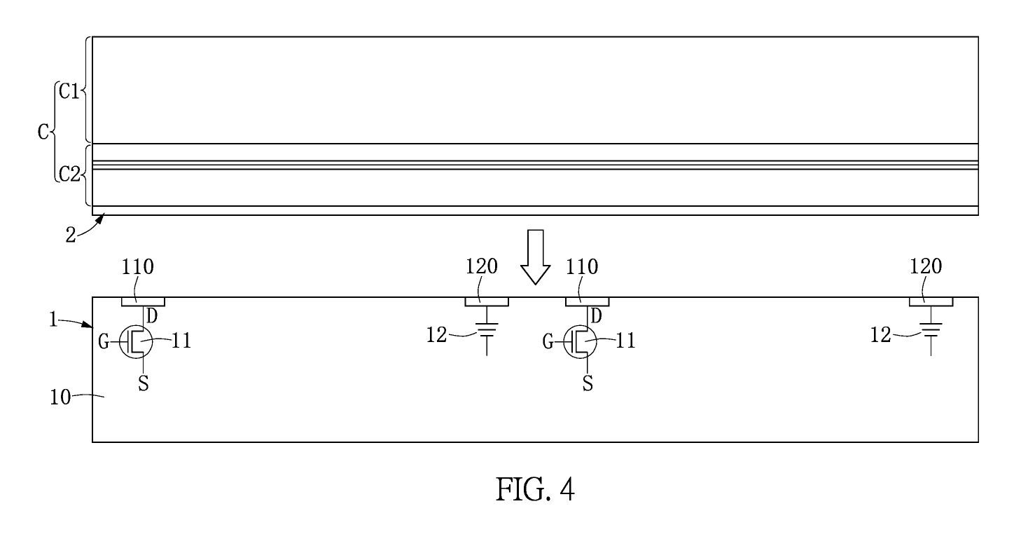

Next, as shown in FIG. 1, FIG. 3 and FIG. 4, a composite structure C and the wafer level substrate 1 are connected by an adhesive layer 2 (step S102(A)). For instance, the thermal expansion coefficient of the adhesive layer 2 is the same as or similar to that of the wafer level substrate 1, and the adhesive layer 2 can be, but is not limited to, a polyetheretherketone (PEEK) adhesive layer, a benzocyclobutene (BCB) adhesive layer or a hydrogen silsesquioxane (HSQ) adhesive layer.

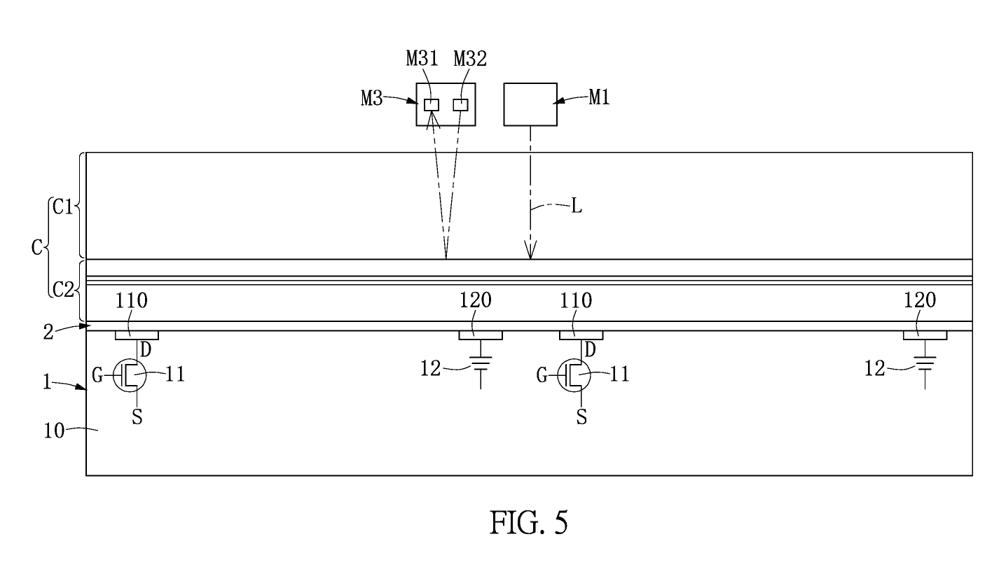

For example, as shown in FIG. 1, FIG. 3 and FIG. 5, step S102 further includes: first, in FIG. 3, forming the adhesive layer 2 on the wafer level substrate 1 (step S1021); and then as shown in FIG. 5, adhering the composite structure C to the adhesive layer 2 to connect the composite structure C and the wafer level substrate 1 to each other (step S1022(A)). However, the abovementioned example is merely one of the possible embodiments and is not intended to limit the present disclose.

For example, as shown in FIG. 1, FIG. 4 and FIG. 5, step S102 further includes: first, in FIG. 4, forming the adhesive layer 2 on the composite structure C (step S1023); and then as shown in FIG. 5, adhering the adhesive layer 2 to the wafer level substrate 1 to connect the composite structure C and the wafer level substrate 1 to each other (step S1024(A)). However, the abovementioned example is merely one of the possible embodiments and is not intended to limit the present disclose.

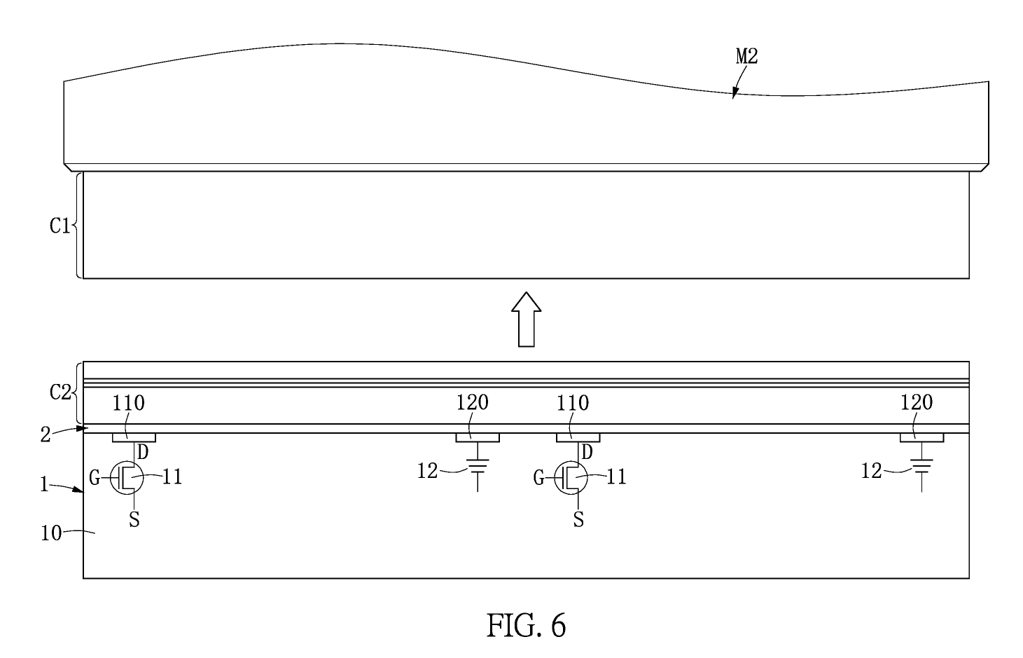

Next, as shown in FIG. 1, FIG. 5 and FIG. 6, a basal layer C1 of the composite structure C (step S104(A)) is removed and a retention layer C2 of the composite structure C (step S106(A)) is retained. For instance, the basal layer C1 of the composite structure C can be a sapphire material layer, and the retention layer C2 of the composite structure C can be a gallium nitride material layer. Furthermore, the basal layer C1 may also be a quartz basal layer, a glass basal layer, a tantalum basal layer or a basal layer of any material, but the present disclosure is not limited thereto.

For example, as shown in FIG. 1, FIG. 5 and FIG. 6, step S104 further includes: first, in FIG. 5, projecting a laser source L generated by a laser generating module M1 onto a contact interface between the basal layer C1 and the retention layer C2 to reduce a bonding force between the basal layer C1 and the retention layer C2 (step S1041); and then shown in FIG. 6, removing the basal layer C1 from the retention layer C2 by a removal module M2 to retain the retention layer C2 being exposed on the adhesive layer M2 (step S1042). In addition, the removal module M2 can be a vacuum cup or any clamping device. However, the abovementioned example is merely one of the possible embodiments and is not intended to limit the present disclose.

For example, as shown in FIG. 1, FIG. 5 and FIG. 6, step S104 further includes: first, in FIG. 5, detecting a position of a contact interface between the basal layer C1 and the retention layer C2 by a position detecting module M3, which includes a sensing element M31 for receiving a detection wave (step S1043); and then as shown in FIG. 5, projecting the laser source L generated by the laser generating module M1 onto the contact interface between the basal layer C1 and the retention layer C2, so as to reduce the bonding force between the basal layer C1 and the retention layer C2 (step S1044); and then shown in FIG. 6, removing the basal layer C1 from the retention layer C2 by the removal module M2 to retain the retention layer C2 being exposed on the adhesive layer M2 (step S1045). In addition, the position detecting module M3 may further include an emission element M32 for emitting a detection wave. Further, the detection wave that the sensing element M31 received may be provided by the emission element M32 or the laser generating module M1. However, the abovementioned example is merely one of the possible embodiments and is not intended to limit the present disclose.

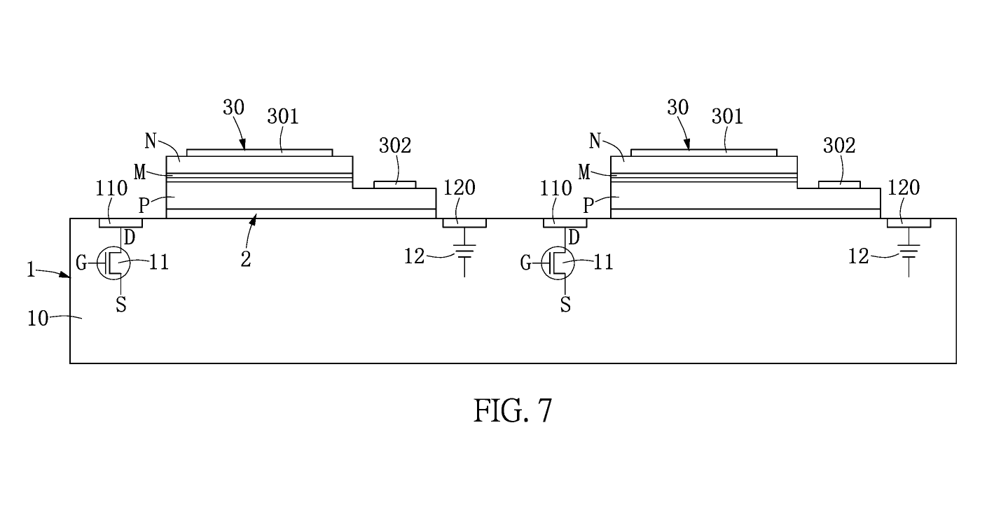

Next, as shown in FIG. 1, FIG. 6 and FIG. 7, the retention layer C2 of the composite structure C is processed into a plurality of light emitting diode structures 30 disposed on the adhesive layer 2 (step S106(A)). For instance, the retention layer C2 may be made into a plurality of light emitting diode structures 30 by semiconductor or non-semiconductor processing. Each of the light emitting diode structures 30 has a first electrode end 301 and a second electrode end 302, and the first electrode end 301 and the second electrode end 302 are further produced on the corresponding light emitting diode structure 30 after the corresponding light emitting 30 was made. In addition, each of the light emitting diode structures 30 includes an n-type conductive layer N, a light emitting layer M and a p-type conductive layer P. The n-type conductive layer N can be n-GaN layer, the light emitting layer can be multiple quantum well (MQW), and the p-type conductive layer P can be p-GaN layer, but the present disclosure is not limited thereto.

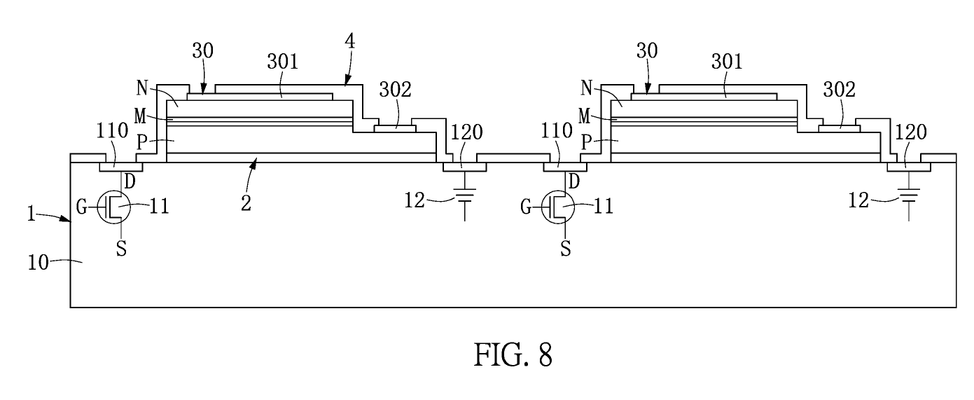

Next, as shown in FIG. 1, FIG. 7 and FIG. 8, an insulating layer 4 is formed on the wafer level substrate 1 and the light emitting diode structures 30 (step S108(A)). For instance, each of the conductive contacts 110 of the control circuits 11, each of the ground contacts 120 of the ground circuits 12, and each of the first electrode ends 301 and each of the second electrode ends 302 of the light emitting structures 30 are entirely or partially exposed from the insulating layer 4. In addition, the insulating layer 4 may be a single insulator or composed of a plurality of insulators, but the present disclosure is not limited thereto.

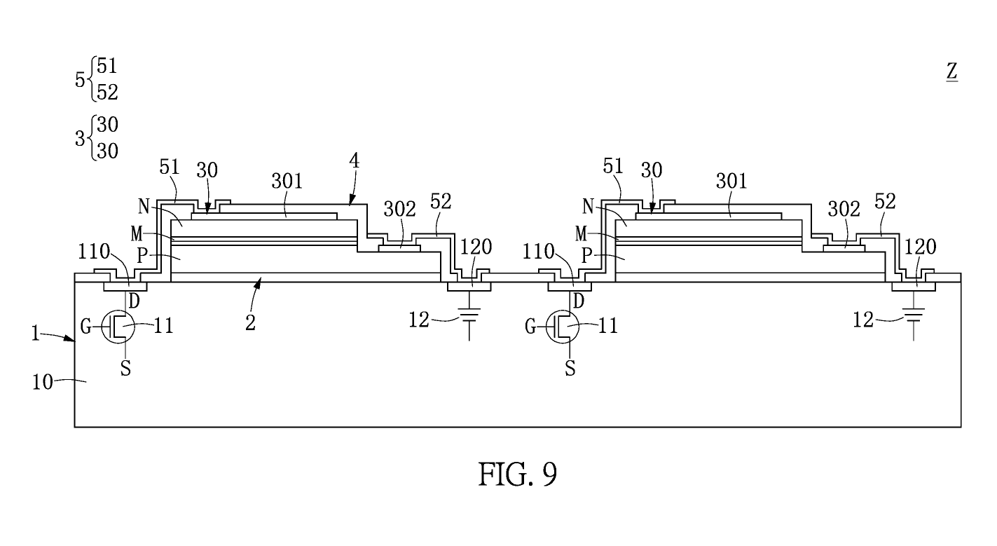

Next, as shown in FIG. 1, FIG. 8 and FIG. 9, a conductive structure 5 is formed to electrically connect between the corresponding light emitting diode structure 30 and the corresponding control circuit 11 (step S110(A)). For instance, the light emitting diode structure 30 can be, but is not limited to, a red light emitting diode, a green light emitting diode, or a blue light emitting diode.

Furthermore, as shown in FIG. 9, the conductive structure 5 includes a plurality of first conductive layers 51 and a plurality of second conductive layers 52. Each of the first conductive layers 51 is electrically connected between the corresponding first electrode end 301 and the corresponding conductive contact 110, and each of the second conductive layers 52 is electrically connected between the corresponding second electrode end 302 and the corresponding ground contact 120.

More particularly, as shown in FIG. 9, each of the first conductive layers 51 can extend along the insulating layer 4 and completely cover the corresponding first electrode end 301 and the corresponding conductive contact 110, and each of the second conductive layers 52 can extend along the insulating layer 4 and completely covers the corresponding second electrode end 302 and the corresponding ground contact 120.

Accordingly, as shown in FIG. 9, the first embodiment of the present disclosure provides a micro LED display Z including a wafer level substrate 1, an adhesive layer 2, a light emitting assembly 3, and a conductive structure 5. The wafer level substrate 1 includes a plurality of control circuits 11. Each of the control circuits 11 has a conductive contact 110. The adhesive layer 2 is disposed on the wafer level substrate 1. The light emitting assembly 3 includes a plurality of light emitting diodes structures 30 disposed on the adhesive layer 2. The conductive structure 5 is electrically connected between the corresponding light emitting diodes structure 30 and the corresponding control circuit 11.

For example, as shown in FIG. 9, the first embodiment of the present disclosure provides the micro LED display Z including a wafer level substrate 1, an adhesive layer 2, a light emitting assembly 3, an insulating layer 4 and a conductive structure 5. The wafer level substrate 1 includes a wafer body 10, a plurality of control circuits 11 which are built in the wafer body 10, and a plurality of ground circuits 12 which are built in the wafer body 10. In addition, each of the control circuits 11 has a conductive contact 110 exposed outside the wafer body 10 and each of the ground circuits 12 has a ground contact 120 exposed outside of the wafer body 10. The adhesive layer 2 is disposed on the wafer body 10. The light emitting assembly 3 includes a plurality of light emitting diodes structures 30 which are disposed on the adhesive layer 2 without contacting the wafer level substrate 1. Each of the light emitting diode structures 30 has a first electrode end 301 and a second electrode end 302. The insulating layer 4 is formed on the wafer level substrate 1 and the light emitting assemblies 3. The conductive contact 110 of each of the control circuits 11, the ground contact 120 of each of the ground circuits 12, and the first electrode end 301 and the second electrode end 302 of each of the light emitting diode structures 30 are exposed from the insulating layer 4. The conductive structure 5 includes a plurality of first conductive layers 51 and a plurality of second conducive layers 52. Each of the first conductive layers 51 is electrically connected between the corresponding first electrode end 301 and the corresponding conductive contact 110, and each of the second conductive layers 52 is electrically connected between the corresponding second electrode end 302 and the corresponding ground contact 120. Therefore, the light emitting diode structures 30 and the wafer level substrate 1 can be separated by the adhesive layer 2 without contacting each other.

### Second Embodiment

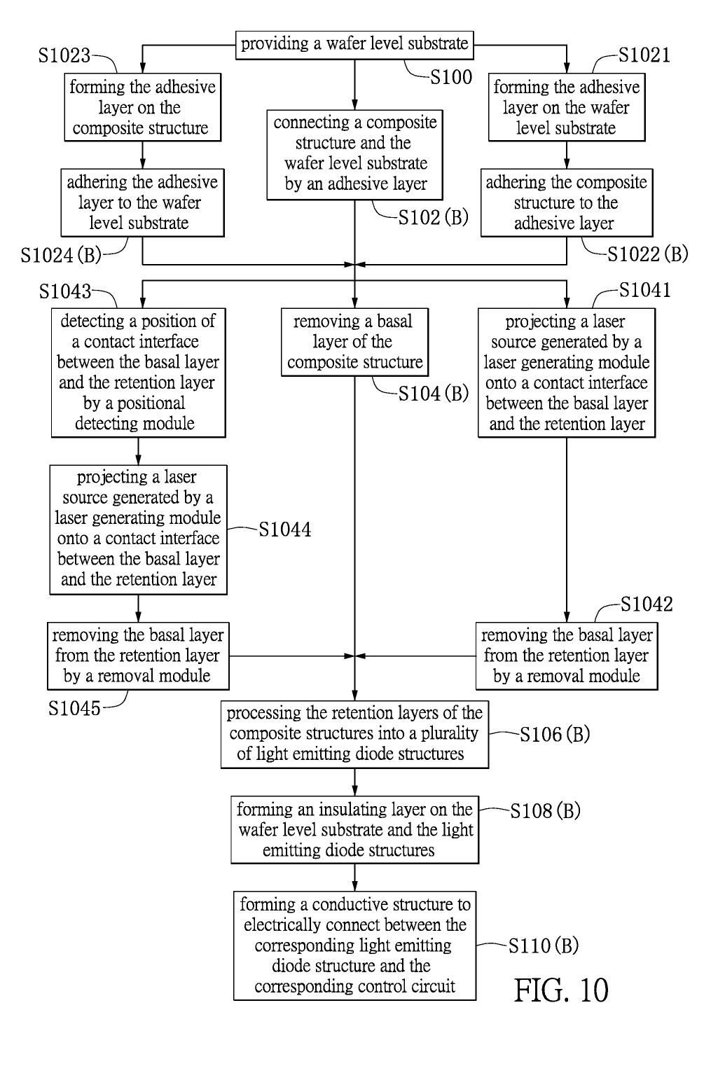

Referring to FIG. 10 to FIG. 15, a second embodiment of the present disclosure provides a micro LED display Z and a method of manufacturing a micro LED display.

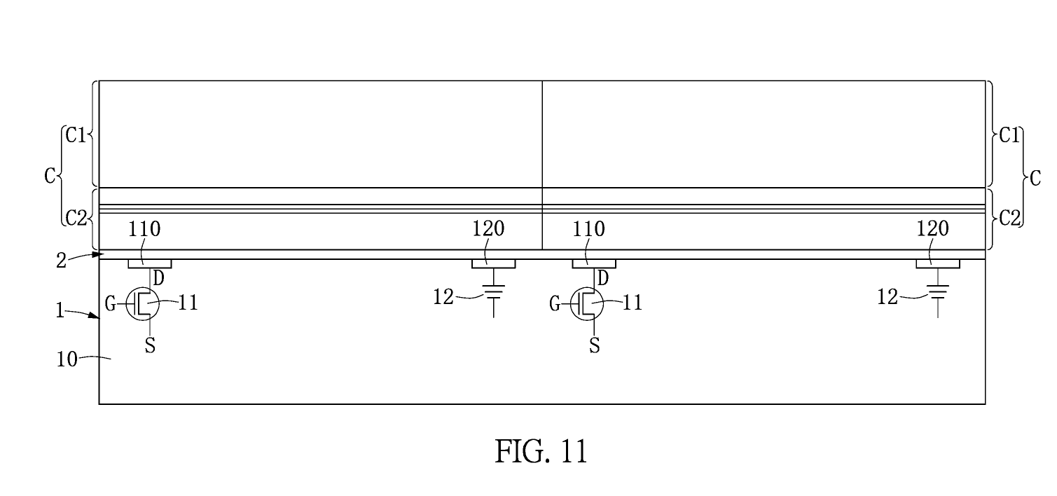

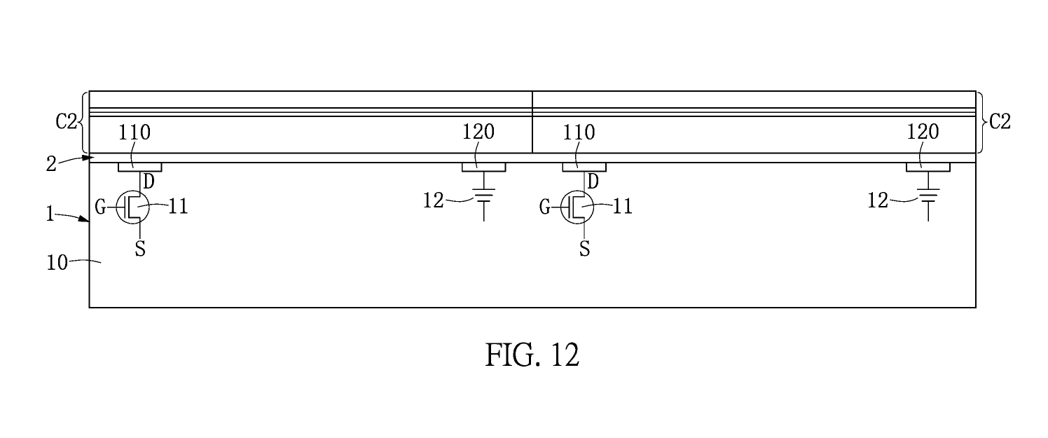

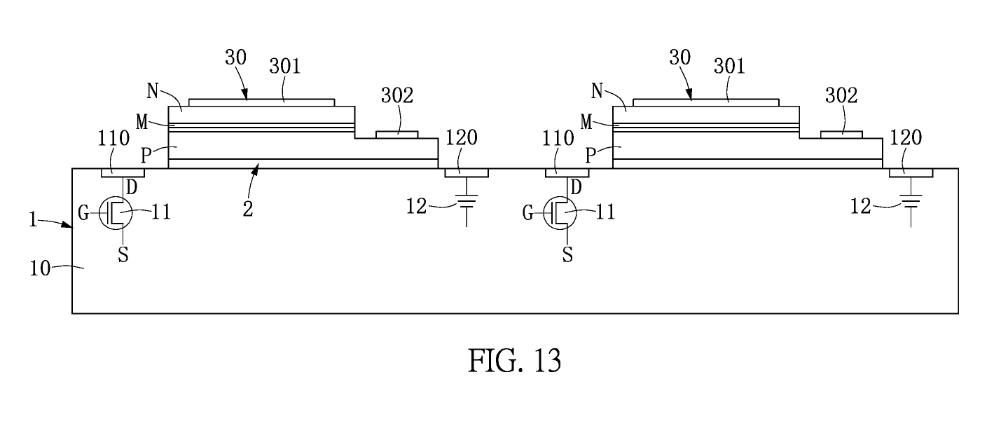

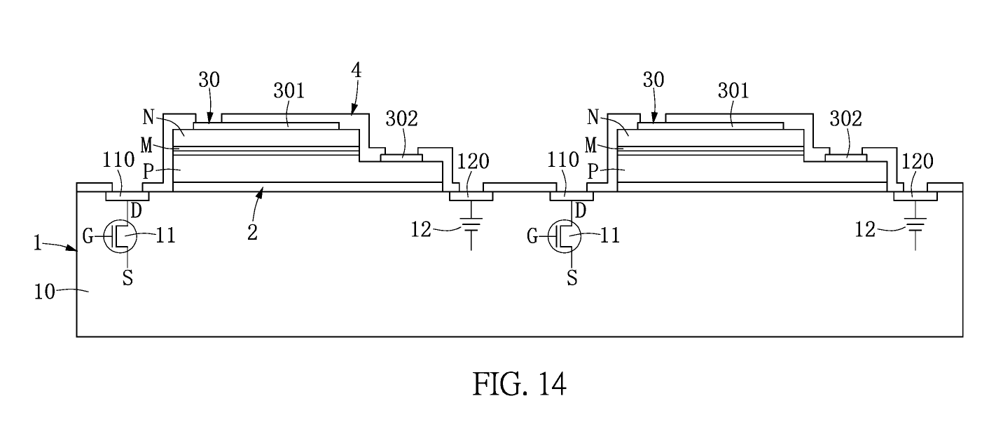

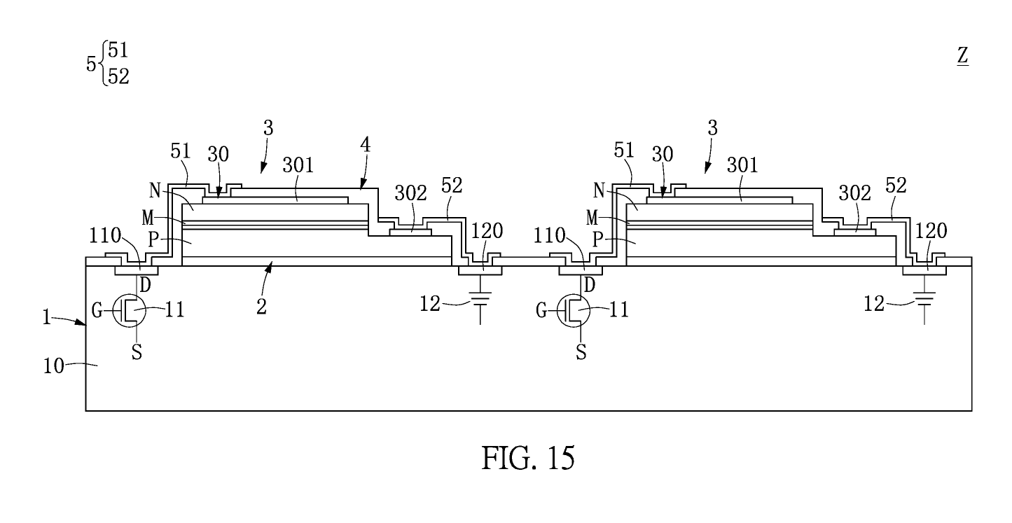

According to a comparison between FIG. 10 and FIG. 1, a comparison between FIG. 11 and FIG. 5, a comparison between FIG. 12 and FIG. 6, a comparison between FIG. 13 and FIG. 7, a comparison between FIG. 14 and FIG. 8, and a comparison between FIG. 15 and FIG. 9, the second embodiment of the method of manufacturing the micro LED display includes: first, as shown in FIG. 10 and FIG. 11, connecting the plurality of composite structures C with the wafer level substrate 1 by the adhesive layer 2 (step S102(B)); next, as shown in FIG. 10 and FIG. 12, removing the basal layer C1 of each of the composite structures C and remaining the retention layer C2 of each of the composite structures C (step S104(B)); and then, as shown in FIG. 10 and FIG. 13, processing the retention layers C2 of the composite structures C into the plurality of light emitting diode structures 30 which are disposed on the adhesive layer 2 (step S106(B)); and as shown in FIG. 10 and FIG. 14, forming the insulating layer 4 on the wafer level substrate 1 and the light emitting diodes structures 30 (step S106(B)); lastly, as shown in FIG. 10 and FIG. 15, forming the conductive structure 5 to electrically connect between the corresponding light emitting diode structure 30 and the corresponding control circuit 11 (step S110(B)).

Furthermore, as shown in FIG. 15, each of the light emitting assemblies 3 includes the plurality of light emitting diodes structures 30 which are disposed on the adhesive layer 2 without contacting the wafer level substrate 1. The insulating layer 4 is formed on the wafer level substrate 1 and the light emitting assemblies 3, and the light emitting assemblies 3 are disposed adjacent to each other so that the light emitting diode structures 30 of the light emitting assemblies 3 are arranged into a pixel array. For instance, the adhesive layer 2 could be in place of a plurality of adhesive bodies, which are corresponding to the light emitting diode structures 30. In other words, each of the light emitting diode structures 30 is disposed on the wafer level substrate 1 with the corresponding adhesive body. In addition, each of the light emitting assemblies 3 in the second embodiment actually includes multiple light emitting diode structures 30, but each of the light emitting assemblies 3 as shown in FIG. 11 to FIG. 15 has only one of the light emitting diode structures 30 as an example.

Accordingly, in the second embodiment, each of the light emitting assemblies 3 actually includes multiple light emitting diode structures 30, so that “the light emitting assemblies 3 which includes the plurality of light emitting diode structures 30” can be adhered on “the wafer level substrate 1 which has the plurality of control circuits 11” by the adhesive layer 2. In other words, in the second embodiment, by using the adhesive layer 2, the light emitting assemblies 3 are attached to the wafer level substrate 1, so that the micro LED display Z can provide a larger display area by splicing the plurality of light emitting assemblies 3 together Moreover, the step S102(B) further includes: forming the adhesive layer 2 on the wafer level substrate 1 (step S1021), and then adhering the composite structure C to the adhesive layer 2 to connect the wafer level substrate 1 and the composite structure C together (step S1022(B)). Or, the step S102(B) further includes: forming the adhesive layer 2 on the wafer level substrate 1 (step S1023), and then adhesive the adhesive layer 2 on the composite structure C to connect the wafer level substrate 1 and the composite structure C together (step S1024(B)).

In conclusion, by combining the features of “the adhesive layer 2 is disposed on the wafer level substrate 1 and each of the light emitting assemblies 3 includes the light emitting diode structures 30 disposed on the adhesive layer 2” and “connecting a plurality of composite structures C and the wafer level substrate 1 by an adhesive layer 2, removing a basal layer C1 of each of the composite structures C and remaining a retention layer C2 of each of the composite structures C, and processing the retention layers C2 of the composite structures C into a plurality of light emitting diode structures 30 which are disposed on the adhesive layer 2”, “the light emitting assemblies 3 which includes the plurality of light emitting diode structures 30” and “the wafer level substrate 1 which has the plurality of control circuits 11” can be connected to each other by the adhesive layer 2.

Notably, since the retention layer C2 can be fabricated into the plurality of light emitting diode structures 30 by semiconductor processing, the size of the light emitting diode structures 30 can be reduced, and the distance between two adjacent light emitting diode structures 30 can be shortened to effectively enhance the image resolution of the micro LED display Z.

Furthermore, each of the light emitting assemblies 3 actually includes a plurality of the light emitting diode structures 30, so that “each of the light emitting assemblies 3 which includes the plurality of the light emitting diode structures 30” can be attached on “the wafer level substrate 1 which has the plurality of control circuits 11” by the adhesive layer 2. In other words, in the second embodiment, by using the adhesive layer 2, the light emitting assemblies 3 are attached to the wafer level substrate 1, so that the micro LED display Z can provide a larger display area by splicing the plurality of light emitting assemblies 3 together.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A micro LED display, comprising:
a wafer level substrate including a wafer body, a plurality of control circuits built in the wafer body, and a plurality of ground circuits built in the wafer body, wherein each of the control circuits has a conductive contact exposed outside of the wafer body, wherein each of the ground circuits has a ground contact exposed outside of the wafer body;
an adhesive layer disposed on the wafer body;
a plurality of light emitting assemblies, wherein each of the light emitting assemblies includes a plurality of light emitting diode structures disposed on the adhesive layer without contacting the wafer level substrate and each of the light emitting diode structures has a first electrode end and a second electrode end;
an insulating layer formed on the wafer level substrate and the light emitting assemblies, wherein the conductive contact of each of the control circuits, the ground contact of each of the ground circuits, and the first electrode end and the second electrode end of each of the light emitting diode structures are exposed from the insulating layer; and
a conductive structure including a plurality of first conductive layers and a plurality of second conducive layers, wherein each of the first conductive layers is electrically connected between the corresponding first electrode end and the corresponding conductive contact, and each of the second conductive layers is electrically connected between the corresponding second electrode end and the corresponding ground contact;
wherein the light emitting assemblies are disposed adjacent to each other, such that the light emitting diode structures of the light emitting assemblies are arranged into a pixel array.

2. The micro LED display according to claim 1, wherein the wafer level substrate is a polished germanium wafer, epitaxial silicon wafer, argon anneal silicon wafer, hai silicon wafer or silicon on insulator silicon wafer; and the control circuit is a CMOS control circuit; wherein the thermal expansion coefficient of the adhesive layer is the same as or similar to that of the wafer level substrate, the adhesive layer is a polyetheretherketone adhesive layer, a benzocyclobutene adhesive layer or a hydrogen silsesquioxane adhesive layer; wherein each of the light emitting diode structures includes a n-type conductive layer, a light emitting layer and a p-type conductive layer, the n-type conductive layer is a n-type gallium nitride material layer, the light emitting layer is a multiple quantum well structure layer, and the p-type conductive layer is a p-type gallium nitride material layer; and wherein each of the first conductive layers extends along the insulating layer and completely covers the corresponding first electrode end and the corresponding conductive contact, and each of the second conductive layers extends along the insulating layer and completely covers the corresponding second electrode end and the corresponding ground contact.

3. A micro LED display, comprising:
a wafer level substrate including a plurality of control circuits, wherein each of the control circuits has a conductive contact;
an adhesive layer disposed on the wafer level substrate;
a plurality of light emitting assemblies, wherein each of the light emitting assemblies has a plurality of light emitting diode structures disposed on the adhesive layer; and
a conductive structure electrically connected between the corresponding light emitting diode structure and the corresponding control circuit;
wherein the light emitting assemblies are disposed adjacent to each other, such that the light emitting diode structures of the light emitting assemblies are arranged into a pixel array.

4. A method of manufacturing a micro LED display comprising the following steps:
providing a wafer level substrate including a plurality of control circuits, wherein each of the control circuits has a conductive contact;
connecting a plurality of composite structures and the wafer level substrate by an adhesive layer;
removing a basal layer of each of the composite structures and remaining a retention layer of each of the composite structures;
processing the retention layers of the composite structures into a plurality of light emitting diode structures disposed on the adhesive layer; and
forming a conductive structure to be electrically connected between the corresponding light emitting diode structure and the corresponding control circuit.

5. The method of manufacturing a micro LED display according to claim 4, wherein the wafer level substrate includes a wafer body and a plurality of ground circuits built in the wafer body, and a plurality of control circuits are built in the wafer body, and the conductive contact of each of the control circuits is exposed outside of the wafer body, and each of the ground circuits has a ground contact exposed outside of the wafer body; wherein the light emitting diode structures and the wafer level substrate are separated from each other by the adhesive layer, and each of the light emitting diode structures has a first electrode end and a second electrode end.

6. The method of manufacturing a micro LED display according to claim 5 further including the following steps before the step of forming the conductive structure:
forming an insulating layer on the wafer level substrate and the light emitting diode structures and the conductive contact of each of the control circuits, the ground contact of each of the control circuits, and the first electrode end and the second electrode end of each light emitting diode structure are exposed from the insulating layer;
wherein the conductive structure includes a plurality of first conductive layers and a plurality of second conducive layers, wherein each of the first conductive layers is electrically connected between the corresponding first electrode end and the corresponding conductive contact, and each of the second conductive layers is electrically connected between the corresponding second electrode end and the corresponding ground contact;
wherein each of the first conductive layers extends along the insulating layer and completely covers the corresponding first electrode end and the corresponding conductive contact, and each of the second conductive layers extends along the insulating layer and completely covers the corresponding second electrode end and the corresponding ground contact.

7. The method of manufacturing a micro LED display according to claim 4, wherein the basal layer of each of the composite structures is a sapphire material layer, and the retention layer of each of the composite structures is a gallium nitride material layer; wherein the step of removing the basal layer of each of the composite structures and remaining the retention layer of each of the composite structures further includes the following steps:
projecting a laser source generated by a laser generating module onto a contact interface between the basal layer and the retention layer to reduce the bonding force between the basal layer and the retention layer, and
removing the basal layer from the retention layer by a removal module to retain the retention layer being exposed on the adhesive layer.

8. The method of manufacturing a micro LED display according to claim 4, wherein the basal layer of each of the composite structures is a sapphire material layer, and the retention layer of each of the composite structures is a gallium nitride material layer; wherein the step of removing the basal layer of each of the composite structures and remaining the retention layer of each of the composite structures further includes the following steps:
detecting a position of a contact interface between the basal layer and the retention layer by a position detecting module which includes at least one sensing element for receiving a detection wave;
projecting a laser source generated by a laser generating module onto the contact interface between the basal layer and the retention layer to reduce the bonding force between the basal layer and the retention layer, and
removing the basal layer from the retention layer by a removal module to retain the retention layer on the adhesive layer and being exposed.

9. The method of manufacturing a micro LED display according to claim 4, wherein the step of connecting the plurality of composite structures with the wafer level substrate by the adhesive layer further includes the following steps:
forming the adhesive layer on the wafer level substrate, and
adhering the composite structures to the adhesive layer to connect each of the composite structures with the wafer level substrate.

10. The method of manufacturing a micro LED display according to claim 4, wherein the step of connecting the plurality of composite structures with the wafer level substrate by the adhesive layer further includes the following steps:
forming the adhesive layer on composite structures, and
adhering the adhesive layer to the wafer level substrate to connect each of the composite structures with the wafer level substrate.
